(19) United States
(12) Patent Application Publication
(10) Pub. No.: US 2023/0411124 A1
(43) Pub. Date: Dec. 21, 2023

(54) CERAMIC COMPONENT WITH CHANNELS

(71) Applicant: Lam Research Corporation, Fremont, CA (US)

(72) Inventors: John Michael KERNS, Livermore, CA (US); David Joseph WETZEL, Santa Clara, CA (US); Lin XU, Fremont, CA (US); Pankaj HAZARIKA, Sherwood, OR (US); Douglas DETERT, Berkeley, CA (US); Lei LIU, Fremont, CA (US); Eric A. PAPE, Santa Cruz, CA (US)

(21) Appl. No.: 18/034,635

(22) PCT Filed: Nov. 1, 2021
(86) PCT No.: PCT/US2021/057581

§ 371 Date: Apr. 28, 2023

Related U.S. Application Data
(60) Provisional application No. 63/115,463, filed on Nov. 18, 2020.
(60) Provisional application No. 63/142,346, filed on Jan. 27, 2021.
(60) Provisional application No. 63/247,187, filed on Sep. 22, 2021.

(51) Int. Cl. H01J 37/32; C04B 41/00; C04B 35/01

(52) U.S. Cl. CPC H01J 37/32477; C04B 41/0054; H01J 37/32467; C04B 2235/94; C04B 2235/666; C04B 2235/6028; C04B 35/01

(57) ABSTRACT

A method for forming a component for a plasma processing chamber is provided. An internal mold is provided. An external mold is provided around the internal mold. The external mold is filled with a ceramic powder, wherein the ceramic powder surrounds the internal mold. The ceramic powder is sintered to form a solid part. The solid part is removed from the external mold.

### CROSS-REFERENCE TO RELATED APPLICATION

This application claims the benefit of priority of U.S. Application No. 63/115,463, filed Nov. 11, 2020, U.S. Application No. 63/142,346, filed Jan. 27, 2021, and U.S. Application No. 63/247,187, filed Sep. 22, 2021, which are incorporated herein by reference for all purposes.

### BACKGROUND

The background description provided here is for the purpose of generally presenting the context of the disclosure. Information described in this background section, as well as aspects of the description that may not otherwise qualify as prior art at the time of filing, are neither expressly nor impliedly admitted as prior art against the present disclosure.

The disclosure relates to parts for use in a plasma processing chamber. More specifically, the disclosure relates to plasma exposed parts in a plasma processing chamber. More specifically, the disclosure relates to a power window for use for passing power into a plasma processing chamber.

Some components of plasma processing chambers, such as power windows require cooling. Cooling may be provided by blowing a cooling gas on a back side of a power window. Such cooling methods have limited capacity. Insufficient cooling may cause nonuniform heating. The nonuniform heating may cause nonuniform processing across a wafer or from wafer to wafer.

Some components of plasma processing chambers, such as power windows, are exposed to plasmas. The plasma may cause degradation of the power window. The degradation of the power window may create contaminants that can cause the failure of the semiconductor devices. Plasma resistant thermal spray coatings, physical vapor deposition (PVD) coatings, chemical vapor deposition coatings (CVD), or atomic layer deposition coatings (ALD) may be applied to power windows. Such coatings have termination points that may be a source of contaminants and erosion. When such coatings are too thick, the coatings are subjected to more cracking.

### SUMMARY

To achieve the foregoing and in accordance with the purpose of the present disclosure, a method for forming a component for a plasma processing chamber is provided. An internal mold is provided. An external mold is provided around the internal mold. The external mold is filled with a ceramic powder, wherein the ceramic powder surrounds the internal mold. The ceramic powder is sintered to form a solid part. The solid part is removed from the external mold.

In another manifestation, a component for use in a plasma processing chamber is provided. A spark plasma sintered ceramic component body has a plasma facing surface. At least one hollow structure is embedded in the ceramic component body.

In another manifestation, an apparatus for processing a wafer is provided. A processing chamber has an inside and outside. A substrate support supports a substrate inside the processing chamber. A gas inlet provides gas into the processing chamber. A coil is outside of the process chamber. A power window is between the coil the inside the process chamber. The power window comprises a spark plasma sintered ceramic component body with a plasma facing surface and at least one serpentine thermal channel extending through the ceramic component body. A thermal control is in fluid connection with the at least one serpentine thermal channel, wherein the thermal control is adapted to flow fluid through the at least one serpentine thermal channel.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of a process that may be used in an embodiment.

FIG. 2A is a top view of an internal mold used in an embodiment.

FIG. 2B is a top view of an external mold used in an embodiment.

FIG. 2C is a side view of an external mold used in an embodiment.

FIG. 2D is a top view of the internal mold in the external mold.

FIG. 2E is a top view of the external mold filled with a base zone powder.

FIG. 2F is a cross-sectional view of the external mold shown in FIG. 2E along cut lines 2F-2F.

FIG. 2G is a top view of the external mold filled with a protective zone powder.

FIG. 2H is a cross-sectional view of the external mold shown in FIG. 2G along cut lines 2H-2H.

FIG. 2I is a cross-sectional view of the external mold in a press and with a pulsed power source.

FIG. 2J is a top view of a solid part removed from an external mold.

FIG. 2K is a cross-sectional view of the solid part shown in FIG. 2J along cut lines 2K-2K.

FIG. 2L is a top view of the solid part after the internal mold is dissolved leaving an empty serpentine channel.

FIG. 2M is a cross-sectional view of the solid part shown in FIG. 2L along cut lines 2M-2M.

FIG. 3 is a schematic view of a plasma processing chamber that is used in an embodiment.

FIG. 4 is a more detailed flow chart of a step of filling an external mold used in an embodiment.

### DETAILED DESCRIPTION

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

Some components of plasma processing chambers, such as power windows are exposed to plasma used to process semiconductor devices. Power windows separate the interior of a plasma processing chamber from the exterior of the plasma processing chamber. A coil is placed outside of the power window. Power is transmitted from the coil through the power window to inside the plasma processing chamber. Power windows may be made of aluminum oxide (Al₂O₃), also called alumina, ceramic. Aluminum oxide ceramic has sufficient mechanical strength, thermal uniformity, low loss RF (radio frequency) transmission, a low cost, a high direct current (DC) electrical resistance, and is easy to machine. When exposed to a fluorine plasma alumina oxide ceramic becomes fluorinated creating particle contaminants. Yttria (Y₂O₃) ceramic may be thermal sprayed onto a plasma facing surface of the power window to provide a protective coating that makes the power window more etch resistant. Such a thermal spray coating has a finite thickness and therefore coating lifetime is limited. In addition, thermal coatings have a termination. Such terminations may be an additional source of particle contaminants. In addition, yttria coatings may have fluorination problems.

Some components of plasma processing chambers, such as power windows require cooling. Heat from power being transmitted through the power window and heat from plasma within the plasma processing chamber increases the temperature of the power window. The higher temperature of the power window may cause degradation of the power window. Cooling may be provided by blowing a cooling gas on a back side of a power window, in order to reduce degradation of the power window. Such cooling methods have limited capacity. Flowing a fluid coolant through such power windows may increase heat transfer. However, metal coolant tubes may interfere with inductive power transmission through the power window. An embodiment provides serpentine thermal channels, such as heating and/or cooling channels in a plasma processing part, such as a power window. The cooling channels may be used to increase thermal uniformity in order to increase process uniformity across a wafer.

Embodiments provide a more erosion resistant dielectric component for a semiconductor processing chamber. In some embodiments, the protective layer is laminated instead of thermal sprayed to eliminate terminations.

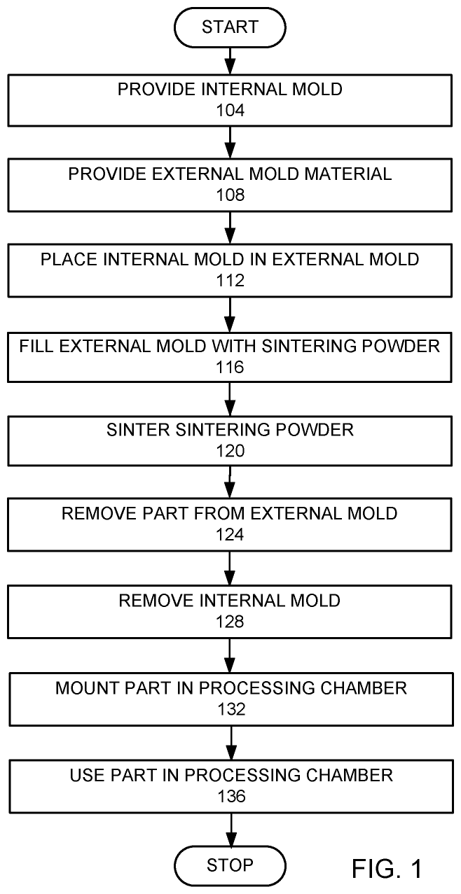

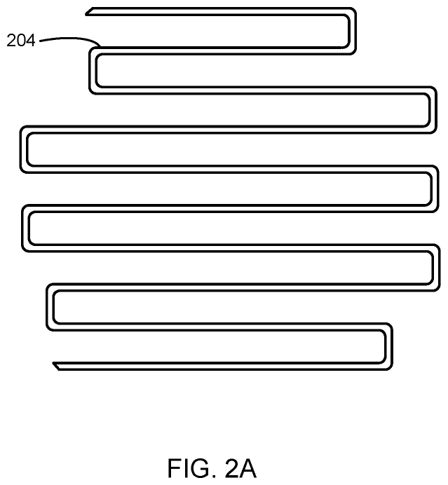

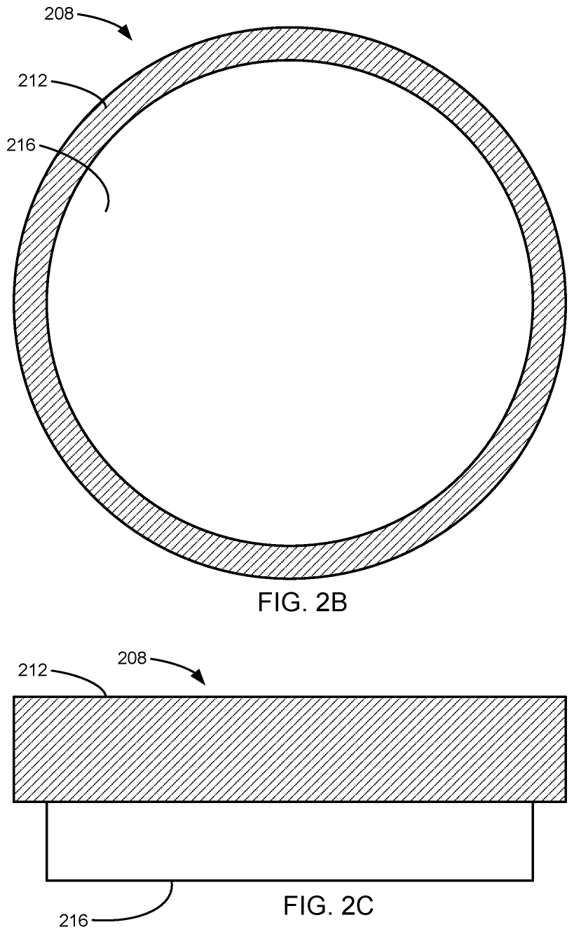

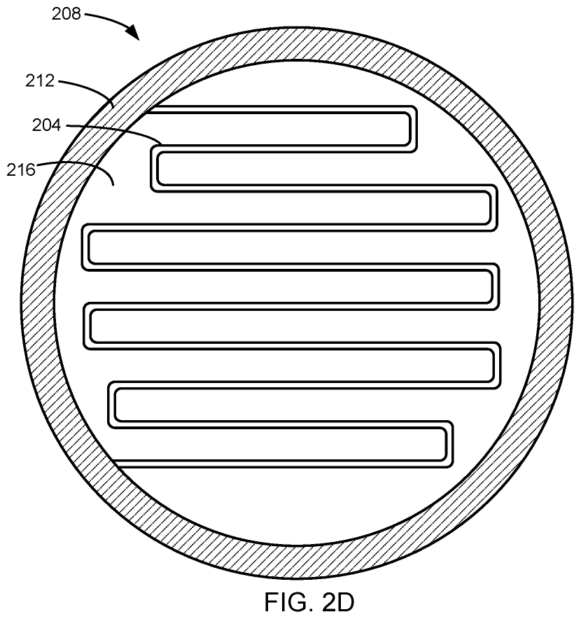

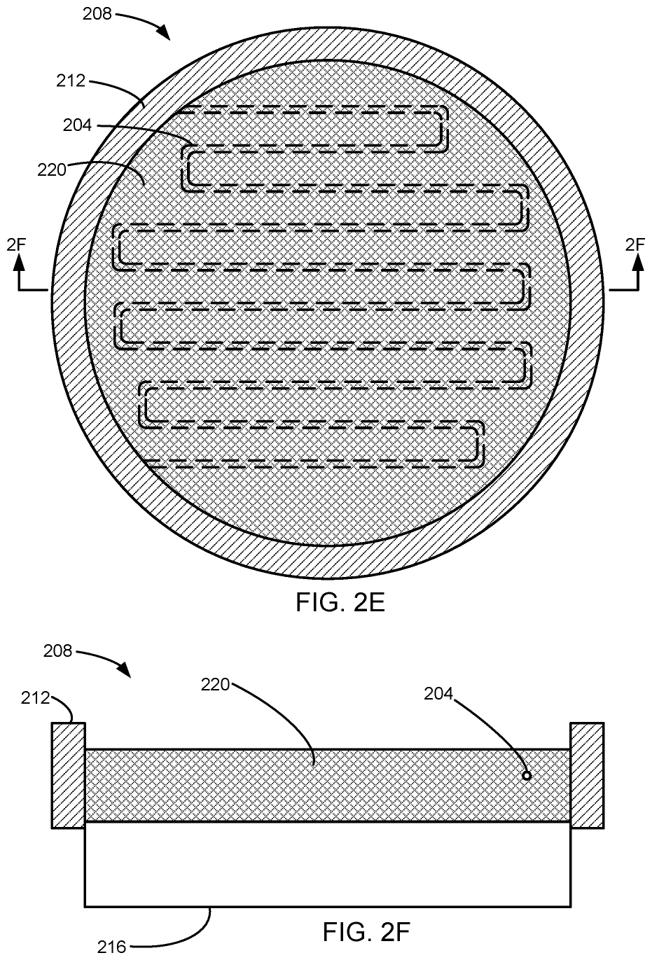

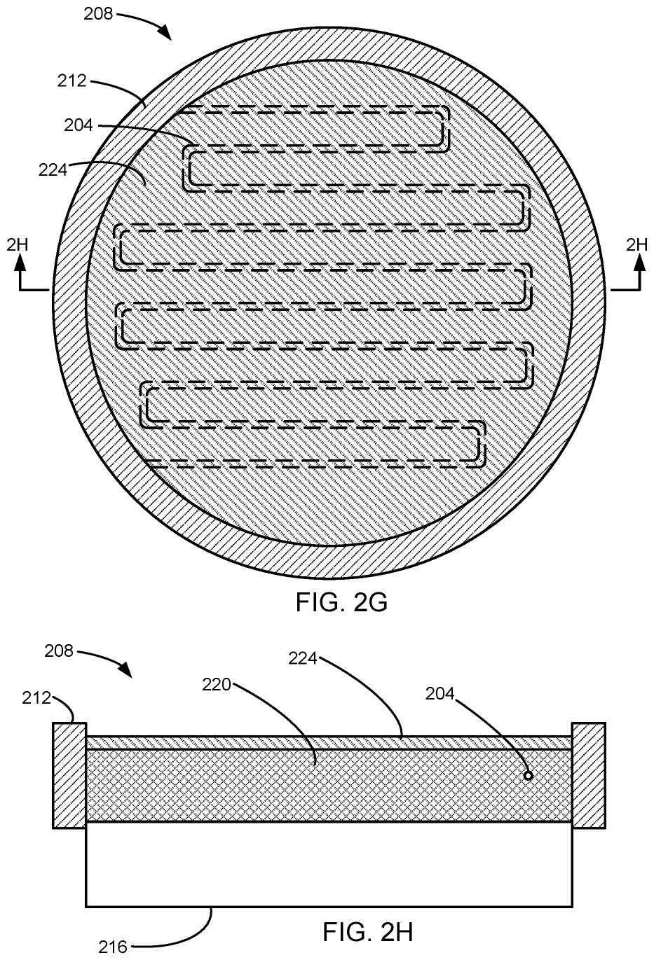

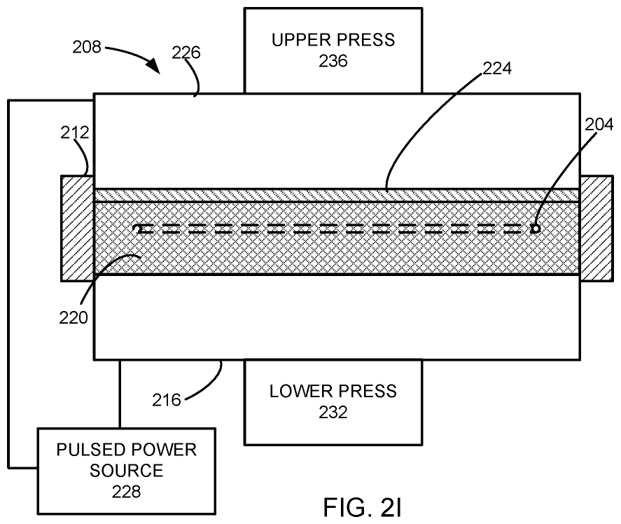

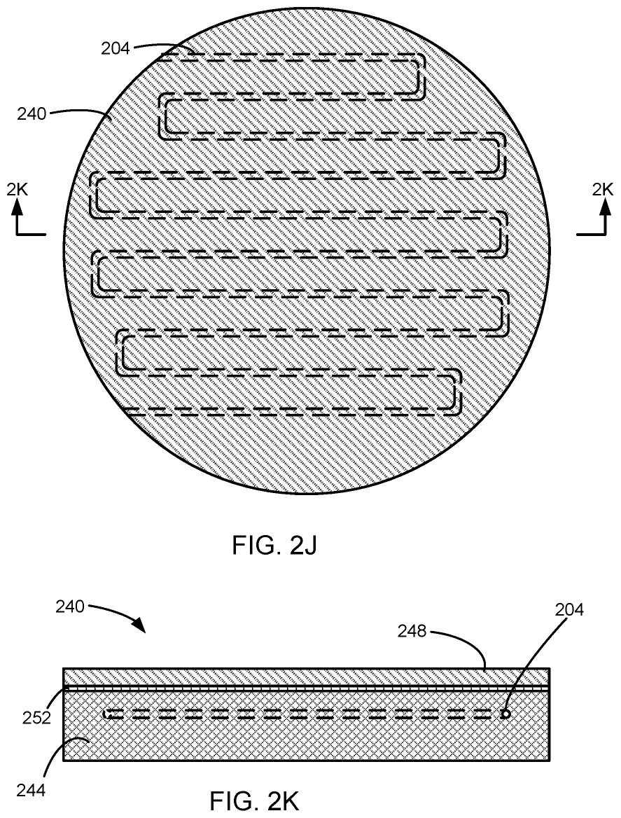

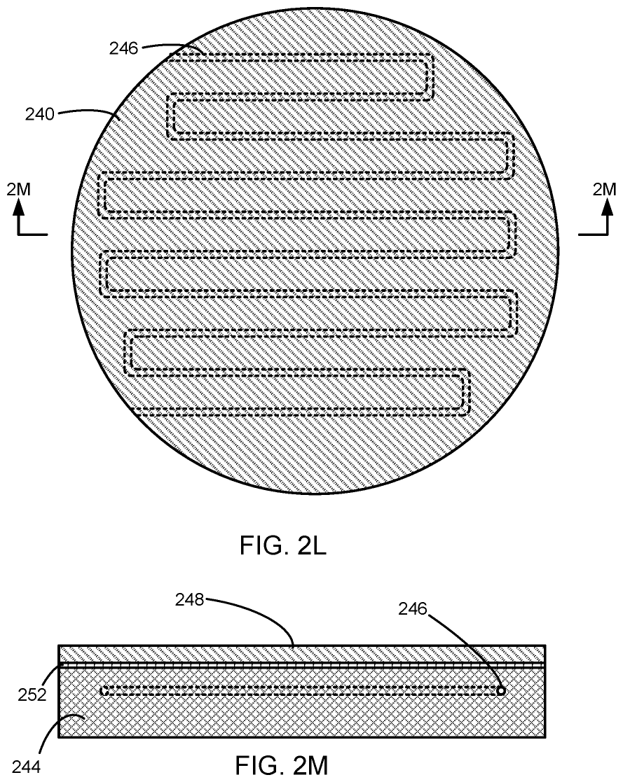

To facilitate understanding, FIG. 1 is a high level flow chart of an embodiment of a method of fabricating and using a component for a plasma processing chamber. An internal mold is provided (step 104). FIG. 2A is a top view of an internal mold 204 provided in an embodiment. In this embodiment, the internal mold 204 is a hollow tube or pipe. For example, the internal mold 204 may be a ceramic or metal hollow tube e.g. a titanium tube. In this embodiment, the internal mold 204 is serpentine. In the specification and claims, the serpentine shape of the internal mold 204 means that the internal mold has a curved portion of over 180° (coiled) or has at least four bends (winding).

In addition to providing an internal mold (step 104), an external mold is provided (step 108). FIG. 2B is a top view of part of an external mold 208. In this example, the external mold 208 comprises an outer ring 212 and a lower punch 216. In this embodiment, the outer ring 212 and the lower punch 216 comprise graphite. FIG. 2C is a side view of the external mold 208, showing the side view of the outer ring 212 and lower punch 216.

The internal mold 204 is place in the external mold 208 (step 112). FIG. 2D is a top view of the internal mold 204 in the external mold 208. In this example, the internal mold 204 contacts the side of the external mold 208 at only two points.

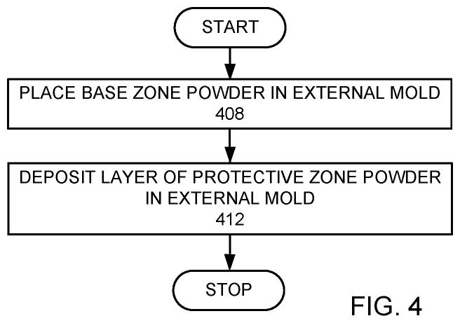

The external mold 208 is filled with a sintering powder that surrounds the internal mold 204 (step 116). FIG. 4 is a more detailed flow chart of the step of filling the external mold 208, used in an embodiment. The external mold 208 is filled with a base zone powder (step 408). In this embodiment, the base zone powder is a first dielectric material comprising a metal oxide powder. In this example, the metal oxide powder comprises a mixture of aluminum oxide and zirconia. In other embodiments, the window body dielectric powder may comprise aluminum nitride and aluminum oxide. FIG. 2E is a top view of the external mold 208 filled with a base zone powder 220. FIG. 2F is a cross-sectional view of the external mold 208 filled with base zone powder 220, shown in FIG. 2E along cut lines 2F-2F. A cross-section of part of the internal mold 204 is shown.

A protective zone powder is placed in the external mold 208 (step 412), providing a layer of the protective zone powder in the external mold 208. In this embodiment, the protective zone powder is a second dielectric material comprising at least one of a mixed metal oxide and a mixed metal oxyfluoride and a metal fluoride, wherein the first dielectric material is different than the second dielectric material. In this example, the protective zone powder comprises at least one of aluminum oxide, yttrium oxide, zirconium oxide, and magnesium oxide, yttrium aluminum oxide, magnesium aluminum oxide, magnesium fluoride, and yttrium aluminum oxyfluoride. In this embodiment, the protective zone powder forms a layer that has a thickness of between about 0.1 mm and 10 mm. In other embodiments, the protective zone powder forms a layer that has a thickness of between about 0.5 mm and 5 mm. FIG. 2G is a top view of the external mold 208 after a protective zone powder 224 has been placed in the external mold 208. FIG. 2H is a cross-sectional view of the external mold 208 filled with base zone powder 220 and the protective zone powder 224, shown in FIG. 2G along cut lines 2H-2H.

The sintering powder comprising the base zone powder 220 and the protective zone powder 224 is then sintered using spark plasma sintering (SPS) to form a solid part (step 120). In this embodiment, an upper punch 226 is placed over the sintering powder, as shown in FIG. 2I. A pulsed power source 228 is electrically connected between the lower punch 216 and the upper punch 226. In this embodiment, the external mold 208 is placed between a lower press 232 and an upper press 236.

As compared to conventional sintering processes, the SPS process (also referred to as pulsed electric current sintering (PECS), Field-Assisted Sintering (FAST) or Plasma Pressure Compaction (P2C)) involves contemporaneous use of pressure and high-intensity, low-voltage (e.g., 5-12 V), pulsed current to dramatically reduce processing/heating times (e.g. 5-10 minutes (min) instead of several hours) and yield high-density components. In one embodiment, a pulsed DC current is transmitted by the pulsed power source 228 through the lower punch 216 and the upper punch 226 to the sintering powder, while pressure (e.g. between 10 megapascals (MPa) up to 500 MPa or more) is simultaneously axially applied to the sintering powder from the lower press 232 and upper press 236 through the lower punch 216 and the upper punch 226 to the sintering powder under mono-axial mechanical force. A “mono-axial force” is herein defined to mean a force applied along a single axis or direction creating mono-axial compression. The external mold 208 is generally placed under vacuum during at least a portion of the process. Pulsed-current patterns (ON:OFF), typically in milliseconds, enable high heating rates (up to 1000° C./min or more), and rapid cooling/quenching rates of (up to 200° C./min or more) for heating the sintering powder to temperatures ranging from under 1000° C. to 2500° C.

In one embodiment of an SPS process, provided for exemplary purposes only, sintering of the composition of sintering powder is conducted under vacuum (6<P (Pascals (Pa))<14) while being simultaneously subjected to a pulsed current. The SPS thermal treatment may be implemented as follows: 1) a degassing treatment performed for a period between 3 minutes (min) to 10 min, and preferably with the sintering powder subjected to 3 min under limited applied load (e.g. between 10 MPa and 20 MPa) and 2 min under increasing load up to 40 MPa to 100 MPa, and 2) heating up to between 1000° C. and 1500° C. at 100° C. min⁻¹ under an applied load between 40 MPa to 100 MPa and a soaking time of 5 min at maximum temperature then cooling down to room temperature. In other embodiments, the temperature range is from 1100° C. to 1300° C. It is appreciated that one or more of the SPS process parameters, including composition constituent ratios and particulate size, pressures, temperatures, treatment periods, and current pulse sequences, may be varied as appropriate to optimize the SPS process.

A solid part formed by the sintering process is removed from the external mold 208 (step 124). FIG. 2J us a top view of solid part 240. FIG. 2K is a cross-sectional view of the solid part 240, shown in FIG. 2J along cut lines 2K-2K. The solid part 240 comprises a component body comprising a base zone 244 formed from the base zone powder, a protective zone 248 formed from the protective zone powder, and a transition zone 252 formed from a mixture of both the base zone powder and the protective zone powder. The transition zone 252 may provide a gradient where near the base zone 244, the transition zone 252 is almost all base zone powder with a little protective zone power, and where the percentage of the protective zone powder increases closer to the protective zone 248 until the transition zone 252 is almost all protective zone powder with a little base zone powder. The gradient provided by the transition zone provides a transition of the coefficient of thermal expansion (CTE) between the base zone 244 and the protective zone 248, reducing cracking due to a CTE mismatch. In addition, the transition zone forms a rough interface that increases adhesion between the base zone 244 and the protective zone 248, reducing delamination, spalling, and flaking. The solid part 240 is characterized by a high degree of densification, reaching nearly 100% (e.g., 99% or greater relative density, and preferably between 99.5% and 100% relative density) with isotropic properties having reduced diffusion between grains and minimized or prevented grain growth. In some embodiments, the average grain size is less than 10 microns (μm). In some embodiments, the average grain size is less than 5 microns. In some embodiments, having a density of at least 99.5% results in a porosity of less than 0.5%, where porosity is defined by the volume of the pores divided by the total volume. The high density and low grain size results in a higher strength part. The internal mold 204 remains in the solid part 240.

The internal mold 204 is removed (step 128). The internal mold 204 may be removed by dissolving the internal mold 204. The internal mold 204 may be dissolved by chemically or thermally reacting the internal mold. In this embodiment, where the internal mold 204 is a titanium tube, the internal mold is chemically dissolved. A hot hydrochloric acid solution may be passed through the internal mold 204 to dissolve the titanium tube. Since the internal mold 204 was in contact with the external mold 208 at two locations, a first location for introducing the hydrochloric acid solution into the titanium tube and a second location for exhausting used solution from the titanium tube are provided where the internal mold 204 contacts the external mold 208. FIG. 2L us a top view of the solid part 240 after the internal mold is dissolved leaving an empty serpentine channel 246. FIG. 2M is a cross-sectional view of the solid part 240, shown in FIG. 2L along cut lines 2M-2M. The solid part 240 forms a spark plasma sintered ceramic component body. Serpentine channel walls are surfaces of the spark plasma sintered ceramic component body.

In other embodiments, the internal mold 204 may be made of iron, zirconium, tungsten, or silicon. If the internal mold 204 is a tungsten tube, then hydrogen peroxide may be used to chemically dissolve the tungsten tube. Hydrochloric acid (HCL) may be used to chemically dissolve iron and zirconium. An aqueous alkaline solution may be used to chemically dissolve silicon. In this embodiment, the internal mold 204 is a titanium tube, so that the internal mold 204 is of a metal material that does not melt at sintering temperatures and has the closest coefficient of thermal expansion (CTE) to the CTE of the aluminum oxide. The closer the CTE of the internal mold 204 is to the CTE of the solid part 240 the less stress is provided over a wide temperature range. Having an internal mold 204 with a CTE that is lower than the CTE of the solid body 204 provides less stress than if the CTE of the internal mold 204 is greater than the CTE of the solid part 240.

In other embodiments, the internal mold 204 may be removed by thermally dissolving the internal mold 204. Different methods of thermally dissolving the internal mold may be by melting the internal mold 204. For example, if the internal mold 204 is tin, graphite, wax, or a thermal plastic polymer, sufficient heat may be provided to melt the internal mold 204. The melted material may be drained or vaporized. In another embodiment, the internal mold 204 may be graphite that is thermally vaporized or burned using heat in order to thermally dissolve the internal mold 204. In other embodiments, the internal mold 204 is not dissolved, but instead used as passage walls for flowing a coolant.

The solid part 240 may be further processed (e.g., grinding, machining, chemical cleaning, physical cleaning, annealing, or like process) to specifically adapt the solid part 240 to be a component for use in a plasma processing chamber. In an embodiment, the dielectric component is subjected to a grinding in order to control the shape and/or the dimensions of the component. An example of a grinding machine that would be used in an embodiment is a computer numerical control (CNC) grinder.

In some embodiments, the further processing may further comprise a thermal annealing that is used to relieve internal mechanical stress. The anneal process is performed after sintering. In some embodiments, multiple anneal processes may be provided. For example, a first anneal process may be provided before polishing and then a second anneal process may be provided after the polishing. In an embodiment, the thermal anneal process is used to heat the dielectric component to a temperature above 600° C. in ambient atmosphere for a period of more than 3 hours. In some embodiments, an oxygen or nitrogen rich environment is provided during the annealing. Different gases may affect the color of the dielectric window. In various embodiments, the annealing is done in a temperature range of 800° C. to 1400° C. for a time period in the range of 3 hours to 72 hours.

Next, the further processing may further comprise subjecting the surface of the protective zone 248 to a lapping process. A lapping process rubs an abrasive compound against the surface of the dielectric component in order to remove part of the surface of the protective zone 248 in order to reduce depth of damage without causing additional depth of damage. Lapping is a slower process than grinding, using a finer material to remove peaks created by the grinding process in order to lower surface roughness without increasing depth of damage. The lapping process may use a fine diamond grit between the component and a plate or pads that provide the rubbing.

After the lapping is completed, the surface of the protective zone 248 is polished. The polishing smooths the surface of the protective zone 248. Polishing is a slower material removal process than lapping. The purpose of polishing is not to remove material, but instead to reduce surface roughness. In an embodiment, a finer grit pad is used to remove peaks and valleys that remain after the lapping process. Polishing lowers surface roughness by reducing the number of peaks and valleys. In some embodiments, only parts of the protective zone 248 exposed to vacuum need to be subjected to the lapping and polishing.

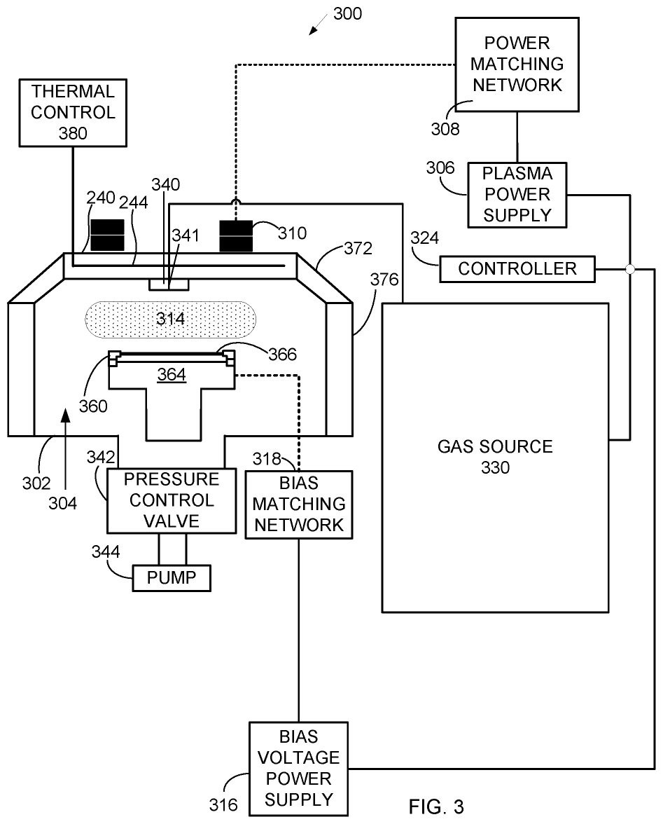

The solid part 240 is mounted as a component of a plasma processing chamber (step 132). To facilitate understanding, FIG. 3 schematically illustrates an example of a plasma processing chamber system 300 that may be used in an embodiment. The plasma processing chamber system 300 includes a plasma reactor 302 having a plasma processing chamber 304 therein. A plasma power supply 306, tuned by a power matching network 308, supplies power to a transformer coupled plasma (TCP) coil 310 located near a dielectric inductive power window formed by the solid part 240. The TCP coil 310 creates a plasma 314 in the plasma processing chamber 304 by providing an inductively coupled power into the plasma reactor 302 through the solid part 240. A pinnacle 372 extends from a chamber wall 376 of the plasma processing chamber 304 to the dielectric inductive power window forming a pinnacle ring. The pinnacle 372 is angled with respect to the chamber wall 376 and the dielectric inductive power window. For example, the interior angle between the pinnacle 372 and the chamber wall 376 and the interior angle between the pinnacle 372 and the dielectric inductive power window may each be greater than 90° and less than 180°. The pinnacle 372 provides an angled ring near the top of the plasma processing chamber 304, as shown. The TCP coil (upper power source) 310 may be configured to produce a uniform diffusion profile within the plasma processing chamber 304. For example, the TCP coil 310 may be configured to generate a toroidal power distribution in the plasma 314. The dielectric inductive power window is provided to separate the TCP coil 310 from the plasma processing chamber 304 while allowing energy to pass from the TCP coil 310 to the plasma processing chamber 304. A wafer bias voltage power supply 316 tuned by a bias matching network 318 provides power to substrate support 364 to set the bias voltage when a process wafer 366 is placed on the substrate support 364. A controller 324 controls the plasma power supply 306 and the wafer bias voltage power supply 316.

The plasma power supply 306 and the wafer bias voltage power supply 316 may be configured to operate at specific radio frequencies such as, for example, 13.56 megahertz (MHz), 27 MHz, 2 MHz, 60 MHz, 400 kilohertz (kHz), 2.54 gigahertz (GHz), or combinations thereof. Plasma power supply 306 and wafer bias voltage power supply 316 may be appropriately sized to supply a range of powers in order to achieve desired process performance. For example, in one embodiment, the plasma power supply 306 may supply the power in a range of 50 to 5000 Watts, and the wafer bias voltage power supply 316 may supply a bias voltage of in a range of 20 to 2000 volts (V). In addition, the TCP coil 310 and/or the substrate support 364 may be comprised of two or more sub-coils or sub-electrodes. The sub-coils or sub-electrodes may be powered by a single power supply or powered by multiple power supplies.

As shown in FIG. 3, the plasma processing chamber system 300 further includes a gas source/gas supply mechanism 330. The gas source 330 is in fluid connection with plasma processing chamber 304 through a gas inlet, such as a gas injector 340. The gas injector 340 has at least one borehole 341 to allow gas to pass through the gas injector 340 into the plasma processing chamber 304. The gas injector 340 may be located in any advantageous location in the plasma processing chamber 304 and may take any form for injecting gas. Preferably, however, the gas inlet may be configured to produce a “tunable” gas injection profile. The tunable gas injection profile allows independent adjustment of the respective flow of the gases to multiple zones in the plasma process chamber 304. More preferably, the gas injector is mounted to the dielectric inductive power window 312. The gas injector may be mounted on, mounted in, or form part of the power window. The process gases and by-products are removed from the plasma process chamber 304 via a pressure control valve 342 and a pump 344. The pressure control valve 342 and pump 344 also serve to maintain a particular pressure within the plasma processing chamber 304. The pressure control valve 342 can maintain a pressure of less than 1 Torr during processing. An edge ring 360 is placed around a top part of the substrate support 364. The gas source/gas supply mechanism 330 is controlled by the controller 324. A Kiyo, Strata, or Vector by Lam Research Corp. of Fremont, CA, may be used to practice an embodiment. In this embodiment, the solid part 240 has a serpentine channel 246. A thermal control 380 is in fluid connection with the serpentine channel 246 and adapted to flow fluid through the serpentine channel 246. The thermal control 380 provides a fluid through the serpentine channel 246. In this embodiment, the thermal control 380 flows a liquid coolant through the serpentine channel 246 to cool the solid part 240. In another embodiment, the thermal control 380 may be used to heat the solid part 240.

The plasma processing chamber is used to plasma process a wafer (step 136). The plasma processing performed by the plasma processing chamber may include one or more processes of etching, depositing, passivating, or another plasma process. The plasma processing may also be performed in combination with non-plasma processing. Transmitting inductive power through the solid part 240 may cause the solid part to heat up. The solid part 240 is cooled to prevent the solid part 240 from degrading. Providing a cooling gas on the backside of the solid part 240 may provide insufficient cooling. Flowing a liquid through the serpentine channel helps to improve process uniformity by providing a more uniform temperature across the solid part 240. The protective zone 248 protects the solid part 240 from plasma erosion.

The protective zone 248 is more plasma erosion resistant than the base zone 244. For example, if the plasma 314 is a fluorine containing plasma, the protective zone 248 may be of a ceramic containing magnesium aluminum oxide and the base zone may be of a ceramic containing zirconia toughened alumina. Magnesium aluminum oxide is more resistant to erosion from a fluorine containing plasma than zirconia toughened alumina. As a result, the protective zone 248 is able to reduce contaminants formed from the solid part 240 caused by the fluorine containing plasma 314 and reduces erosion of the solid part 240. In various embodiments, the protective zone 248 may be made from at least one of a mixed metal oxide, a mixed metal oxyfluoride, and a metal fluoride. In various embodiments, the mixed metal oxide, the mixed metal oxyfluoride, and the metal fluoride may comprise at least one of yttrium aluminum oxide, magnesium aluminum oxide, magnesium fluoride, and yttrium aluminum oxyfluoride.

Using zirconia toughened alumina ceramic for the base zone 244 provides increased mechanical strength, thermal uniformity, low loss RF (radio frequency) transmission, and with a high DC electrical resistance. The DC electrical resistance of zirconia toughened alumina is greater than 10⁶ ohms. In addition, zirconia toughened alumina ceramic is easy to machine. Also, zirconia toughened alumina ceramic has a low cost. Since only most of the solid part 240 should have good mechanical strength and only a small thickness of the solid part 240 needs improved plasma erosion resistance the thickness of the base zone 244 is several times thicker than the protective zone 248. In this embodiment, the protective zone 248 has a thickness of between 0.1 mm and 10 mm. In other embodiments, the protective zone 248 has a thickness of between about 0.5 mm and 5 mm. The solid part 240 may have a thickness between about 10 mm and 100 mm. In some embodiment, the dielectric component 240 has a thickness between about 20 mm to 50 mm. The transition zone 252 may have a thickness of between about 1 μm and 40 μm. Because the spark plasma sintering process is much faster than other sintering processes there is less inter-diffusion of the different materials, so that the transition zone 252 of a spark plasma sintering process would be thinner than other sintering processes that heat for longer periods of time. In addition, the transition zone 252 would be much thicker than a transition zone that results from a thermal spray process. Thermal spray processes have little diffusion so that the transition zone would be much thinner than a transition zone produced by an SPS process. Some other sintering processes cause cracking due to the coefficient of thermal expansion mismatch. In some embodiments, more than 90% of the solid part 240 is formed by the base zone 244. In various embodiments, the base zone 244 is made of at least one of aluminum oxide, aluminum nitride, yttrium stabilized zirconia, and zirconium toughened alumina.

In other embodiments, the solid part 240 may form other parts of the plasma processing chamber system 300. For example, the solid part 240 may be walls of the plasma processing chamber. More specifically, the solid part 240 may be walls of a plasma processing chamber system 300 where inductive power is passed through the solid part 240 from the outside of the plasma processing chamber system 300 into the plasma processing chamber system 300.

In other embodiments, the components may be parts of other types of plasma processing chambers such as a bevel plasma processing chambers or like device. Examples of components of plasma processing chambers that may be provided in various embodiments are power windows, wall, liners, such as a pinnacle, showerheads, gas injectors, and edge rings of plasma processing chambers. In various embodiments, the power windows may be flat, or dome shaped, or have other shapes.

In other embodiments for chemically reacting an internal mold 204, the internal mold 204 is formed from a mold powder, comprising a base powder and an acid powder. To chemically react the internal mold, water is provided to the internal mold. The water causes acid powder to neutralize base powder dissolving the internal mold 204.

Various embodiments may provide walls between channels with a thickness of greater than 6 mm. Using current technology, if similar parts were produced using 3D printing with walls greater than 6 mm thick, such parts would be subject to cracking. In addition, such 3D printed parts would have other detrimental properties. Therefore, 3D printed parts should not have walls between thermal channels that are thicker than 6 mm.

In other embodiments, a plasma resistant coating may be formed on a plasma facing surface of the solid part 240 using a plasma spray, thermal spray, or other deposition or formation processes. It is appreciated that the mold and/or SPS process may be structured so that the further processing of the solid part 240 is not required. In some embodiments, a plasma resistant coating is not provided.

In some embodiments, the protective zone powder 224 may be placed in the mold before the base zone powder 220. It may be difficult to provide a uniform and thin layer of the protective zone powder 224 while adding a thicker layer of the base zone powder 220.

In various embodiments, a ternary ceramic may be formed at least one of two different ways. In some embodiments, a ternary ceramic powder may be used. In other embodiments, two binary ceramic powders may be used. For example, in order to form a magnesium aluminum oxide protective zone 248, the protective zone powder may comprise two binary ceramic powders of magnesium oxide and aluminum oxide. During sintering, a reactive sintering process takes place causing the two binary ceramic powders to form the ternary ceramic of magnesium aluminum oxide. In another embodiment, the protective zone powder is a ternary ceramic powder of magnesium aluminum oxide powder. The magnesium aluminum oxide powder is sintered to form a magnesium aluminum oxide part. In another embodiment, the magnesium aluminum oxide powder is sintered in the presence of fluorine gas to form a magnesium aluminum oxyfluoride ceramic part.

By co-firing the different base zone powder 220 and the protective zone powder 224 the different base zone 244 and protective zone 248 are formed as layers laminated together. These laminated layers have a bonding that prevents separation and termination. The low porosity of the solid part 240 further reduces erosion.

In various embodiments, a protective zone may have a thickness of about 5 mm. In some embodiments, less than 4 mm of the protective zone is eroded in 10,000 RF hours of use. Such an embodiment allows for use of the solid part 240 for about 10,000 RF hours without requiring a changing of the solid part 240. Having a part that lasts for 10,000 RF hours reduces maintenance costs, contamination, process drift, and downtime.

In some embodiments, a base zone 244 of zirconium toughened alumina is used with a protective zone 248 of yttrium aluminum oxide. Zirconium toughened alumina and yttrium aluminum oxide have coefficients of thermal expansion that are close enough to reduce cracking.

While this disclosure has been described in terms of several preferred embodiments, there are alterations, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A method for forming a component for a plasma processing chamber, comprising:
providing an internal mold;
providing an external mold around the internal mold;
filling the external mold with a ceramic powder, wherein the ceramic powder surrounds the internal mold;
sintering the ceramic powder to form a solid part; and
removing the solid part from the external mold.

2. The method, as recited in claim 1, wherein the sintering the ceramic powder is spark plasma sintering.

3. The method, as recited in claim 1, wherein the ceramic powder is a metal oxide.

4. The method, as recited in claim 1, wherein the internal mold is in contact with the external mold.

5. The method, as recited in claim 1, further comprising removing the internal mold, by a process comprising dissolving, melting, chemically reacting, vaporizing, thermally reacting, or a combination thereof.

6. The method, as recited in claim 1, wherein the internal mold comprises at least one hollow tube, and further comprising removing the internal mold comprising flowing a fluid through the at least one hollow tube, wherein the fluid chemically dissolves the at least one hollow tube.

7. The method, as recited in claim 1, wherein the filling the external mold with a ceramic powder, wherein the ceramic powder surrounds the internal mold, comprises:
providing a base zone powder in a mold, wherein the base zone powder comprises a first dielectric material, wherein the base zone powder surrounds the internal mold; and
providing a layer of a protective zone powder in the mold, wherein the protective zone powder comprises a second dielectric material different from the first dielectric material, wherein the sintering the ceramic powder co-sinters the base zone powder and protective zone powder.

8. The method, as recited in claim 7, wherein the second dielectric material comprises at least one of yttrium aluminum oxide, magnesium aluminum oxide, yttria, magnesium oxide, magnesium fluoride, and yttrium aluminum oxyfluoride and wherein the first dielectric material comprises at least one of aluminum oxide, aluminum nitride, yttrium stabilized zirconia, and zirconium toughened alumina.

9. A component for use in a plasma processing chamber, comprising
a spark plasma sintered ceramic component body with a plasma facing surface; and
at least one hollow structure embedded in the ceramic component body.

10. The component, as recited in claim 9, wherein the hollow structure comprises a serpentine thermal channel extending through the ceramic component body.

11. The component, as recited in claim 10, wherein walls between the serpentine thermal channel has a thickness of greater 6 mm.

12. The component, as recited in claim 9, wherein walls of the at least one hollow structure is formed by the spark plasma sintered ceramic component body.

13. The component, as recited in claim 9, wherein the ceramic component body forms at least one of a power window, liner, showerhead, and edge ring.

14. The component, as recited in claim 9, wherein the ceramic component body comprises:
a base zone, wherein the base zone comprises a first dielectric material;
a protective zone on a first side of the base zone, wherein the protective zone comprises a second dielectric material of at least one of a mixed metal oxide and a mixed metal oxyfluoride and a metal fluoride, wherein the first dielectric material is different than the second dielectric material; and
a transition zone between the protective zone and the base zone, wherein the transition zone has a thickness of between about 1 μm and 40 μm and wherein the transition zone comprises the first dielectric material and the second dielectric material.

15. An apparatus for processing a wafer, comprising:
a processing chamber with an inside and outside;
a substrate support for supporting a substrate inside the processing chamber;
a gas inlet for providing gas into the processing chamber;
a coil outside of the process chamber;
a power window between the coil the inside the process chamber, wherein the power window comprises:
a spark plasma sintered ceramic component body with a plasma facing surface; and
at least one serpentine thermal channel extending through the ceramic component body; and
a thermal control in fluid connection with the at least one serpentine thermal channel, wherein the thermal control is adapted to flow fluid through the at least one serpentine thermal channel.

16. The apparatus, as recited in claim 15, wherein walls of the at least one serpentine thermal channel are formed by the ceramic component body.

17. The apparatus, as recited in claim 15, wherein the spark plasma sintered ceramic component body comprises:
a base zone, wherein the base zone comprises a first dielectric material;
a protective zone on a first side of the base zone, wherein the protective zone comprises a second dielectric material of at least one of a mixed metal oxide and a mixed metal oxyfluoride and a metal fluoride, wherein the first dielectric material is different than the second dielectric material; and
a transition zone between the protective zone and the base zone, wherein the transition zone has a thickness of between about 1 μm and 40 μm and wherein the transition zone comprises the first dielectric material and the second dielectric material.

18. A power window for use in a plasma processing chamber, comprising
a spark plasma sintered ceramic component body with a plasma facing surface with a density of at least 99.5% and an average grain size of less than 10 microns; and
a serpentine channel within the ceramic component body.

19. The power window, as recited in claim 18, wherein the serpentine channel is defined by serpentine channel walls, wherein the serpentine channel walls are surfaces of the spark plasma sintered ceramic component body.

20. The power window, as recited in claim 18, wherein the spark plasma sintered ceramic component body comprises:
a base zone, wherein the base zone comprises a first dielectric material;
a protective zone on a first side of the base zone, wherein the protective zone comprises a second dielectric material of at least one of a mixed metal oxide and a mixed metal oxyfluoride and a metal fluoride, wherein the first dielectric material is different than the second dielectric material; and
a transition zone between the protective zone and the base zone, wherein the transition zone has a thickness of between about 1 μm and 40 μm and wherein the transition zone comprises the first dielectric material and the second dielectric material.
